(19) United States
(12) Patent Application Publication
(10) Pub. No.: US 2025/0391757 A1
(43) Pub. Date: Dec. 25, 2025

(54) SUBSTRATE DESIGN FOR SEMICONDUCTOR PACKAGE AND MANUFACTURING METHOD THEREOF

(71) Applicant: Taiwan Semiconductor Manufacturing Company, Ltd., Hsinchu (TW)

(72) Inventors: Wei-Hsuen Lee, Hsinchu City (TW); Hungen Hsu, Hsinchu (TW); Kuo-Ching Hsu, Taipei (TW)

(73) Assignee: Taiwan Semiconductor Manufacturing Company, Ltd., Hsinchu (TW)

(21) Appl. No.: 18/747,488

(22) Filed: Jun. 19, 2024

(51) Int. Cl. H01L 23/498; H01L 21/48

(52) U.S. Cl. CPC H01L 23/49838; H01L 21/4857; H01L 21/486; H01L 23/49822

(57) ABSTRACT

A substrate structure includes a first core structure and a build-up structure. The first core structure includes a first side, a second side opposite to each other, a first core layer, and a first core dielectric layer wrapping around the first core layer, where the first core layer is non-organic. The build-up structure is disposed on the first and second sides of the first core structure, the build-up layer includes a first dielectric layer at least covering the first side of the first core structure, and materials of the first dielectric layer and the first core dielectric layer are different.

### BACKGROUND

With the advancement of modern technologies, integrated circuits having more functions and greater performance are increasingly demanded. In the packaging of integrated circuits, one or more semiconductor chips (or dies) are mounted on a substrate. Advanced substrates are introduced for enhanced electrical performance in semiconductor packages, but are also expected to reduce stresses in the semiconductor packages.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1I are schematic cross-sectional views of various stages of manufacturing a substrate structure, in accordance with some embodiments.

FIGS. 2-6 are schematic cross-sectional views of various variations of a substrate structure, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

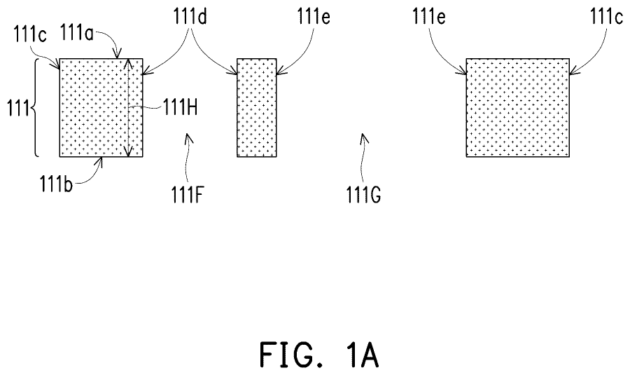

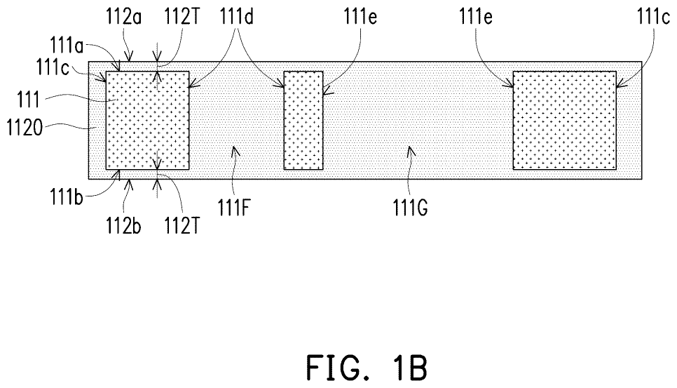

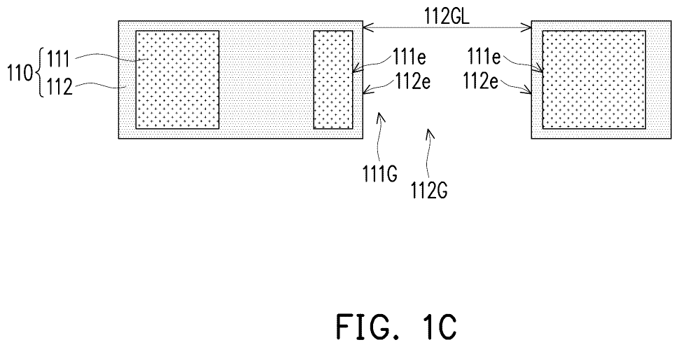

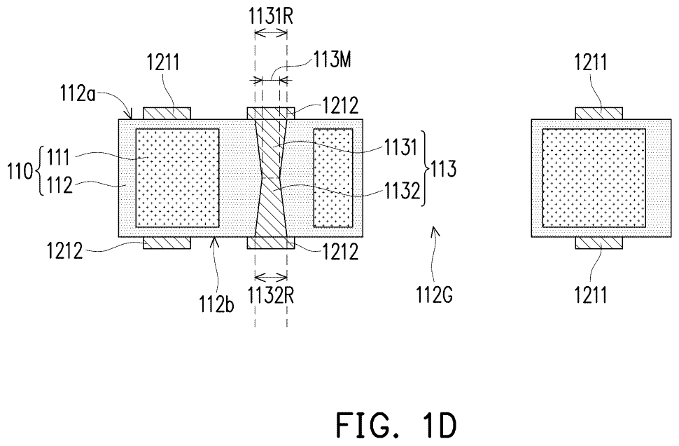

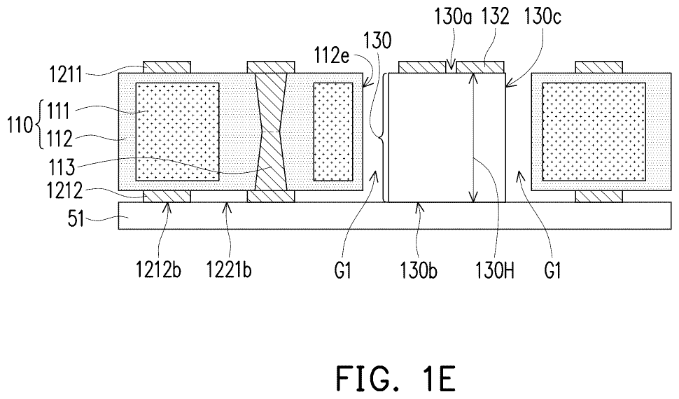

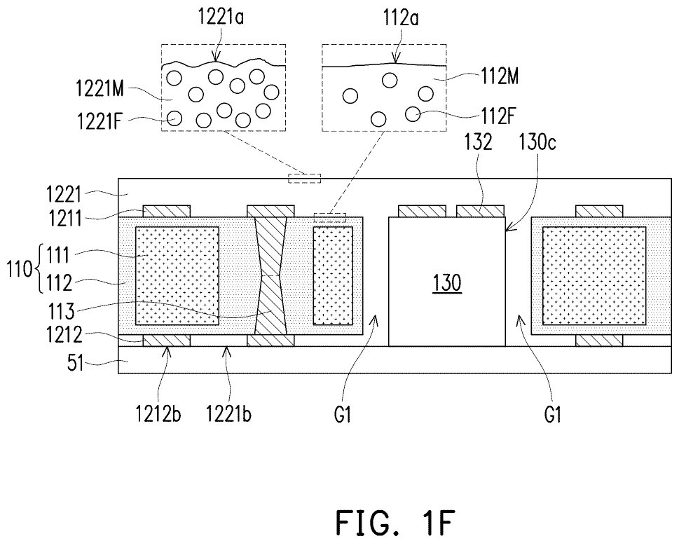

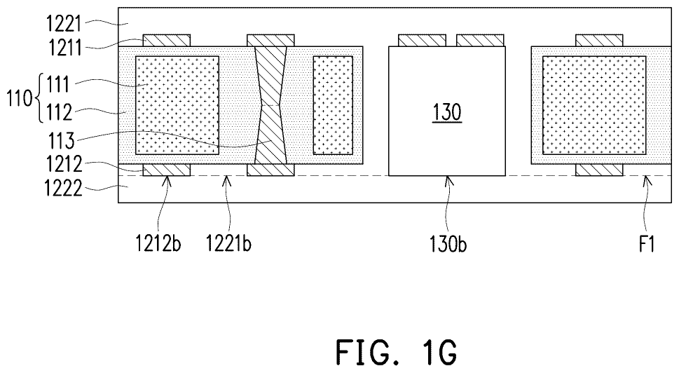

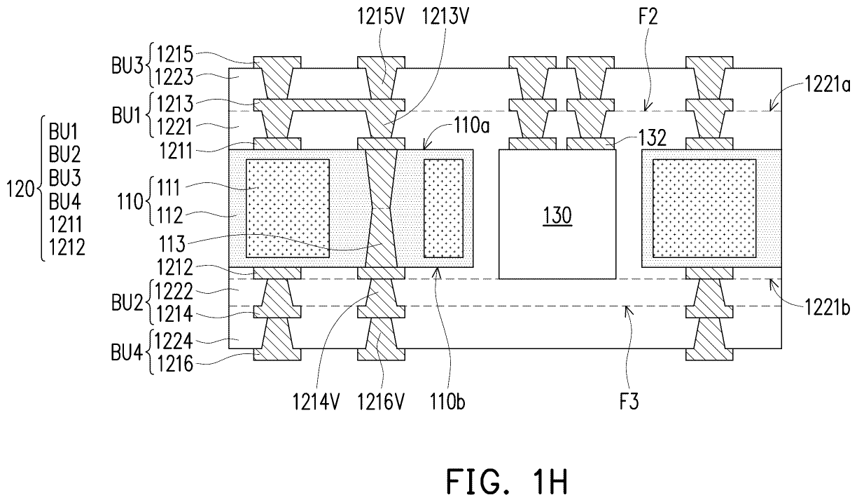

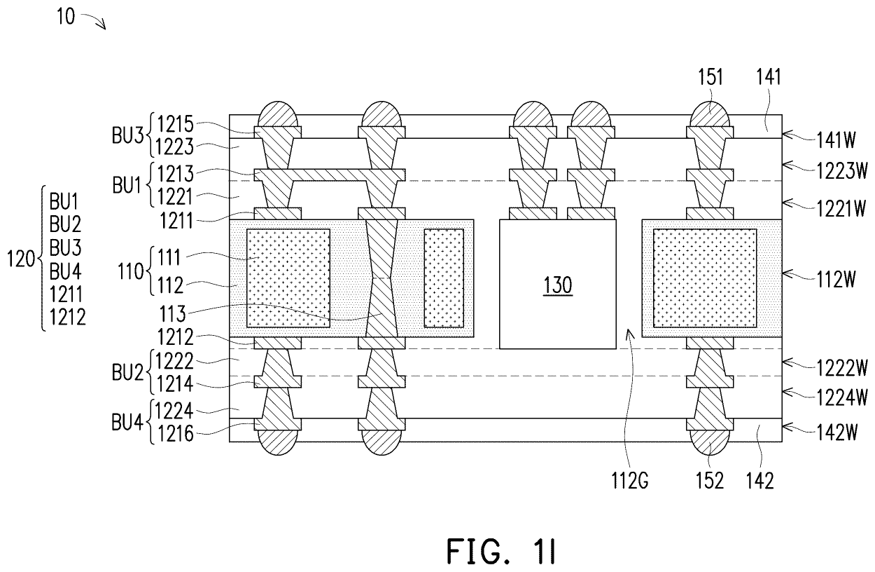

FIGS. 1A-1I are schematic cross-sectional views of various stages of manufacturing a substrate structure, in accordance with some embodiments. Referring to FIG. 1A, a core layer 111 including through holes (e.g., a first through hole 111F and a second through hole 111G) may be provided. For example, a core material layer is provided, and then the core material layer is patterned through suitable removal process (e.g., laser drilling, etching, the like, a combination thereof, etc.) to form the core layer 111 having the first and second through holes (111F and 111G). In some embodiments, the core layer 111 is made of a material that is non-organic or inorganic. The core layer 111 may be referred to as a non-organic (or inorganic) core. For example, the core layer 111 is fabricated from a ceramic material, quartz, glass, metal (e.g., aluminum, alloy, etc.), the like, combinations thereof, etc. In some embodiments, the tensile strength of the core layer 111 is in a range of about 1500 MPa and over about 3000 MPa. The core layer 111 may have a Young's modulus in a range from about 95 GPa to about 310 GPa. In some embodiments, the core layer 111 is made of one or more low dissipation factor (or called dielectric loss tangent, Df) material(s). In some embodiments, the dielectric constant (under 1 MHz) of the core layer 111 is in a range of about 5 and about 7. It is realized that the values of the tensile strength, Young's modulus, and the dielectric constant herein are merely examples, and may be changed to other suitable values.

With continued reference to FIG. 1A, the core layer 111 may include a first surface 111a, a second surface 111b opposite to the first surface 111a, an outer sidewall 111c connected to the first surface 111a and the second surface 111b. In some embodiments, the thickness 111H of the core layer 111 measured between the first surface 111a and the second surface 111b is in a range of about 200 μm to about 400 μm, or some other suitable value. The first through hole 111F and the second through hole 111G may each pass through the first surface 111a and the second surface 111b. The first through hole 111F may be defined by a first inner sidewall 111d, and the second through hole 111G may be defined by a second inner sidewall 111e. The first inner sidewall 111d and the second inner sidewall 111e may be formed after patterning the core material layer as mentioned in the previous paragraph. It is appreciated that two through holes are illustrated as examples, and a single through hole or more than two through holes are possible. In addition, depending on process and product requirements, the sizes of the through holes in the core layer 111 construe no limitation in the disclosure.

Referring to FIG. 1B with reference to FIG. 1A, the core layer 111 may be buried in a core dielectric material 1120. The core dielectric material 1120 may wrap around the core layer 111. All surfaces of the core layer 111 may be covered by the core dielectric material 1120. For example, the first surface 111a, the second surface 111b, the outer sidewall 111c, and the first and second inner sidewalls (111d and 111e) of the core layer 111 are covered by the core dielectric material 1120. In some embodiments, a thickness 112T of the core dielectric material 1120 measured between the first surface 112a of the core dielectric material 1120 and the first surface 111a of the core layer 111 is in a range of about 10 μm to about 200 μm, or some other suitable value. In some embodiments, the thickness of the core dielectric material 1120 measured between the second surface 112b of the core dielectric material 1120 and the second surface 111b of the core layer 111 is substantially equal to the thickness 112T. Alternatively, the thickness of the core dielectric material 1120 measured between the second surface 112b of the core dielectric material 1120 and the second surface 111b of the core layer 111 is different from the thickness 112T and ranges from about 10 μm to about 200 μm, or some other suitable value.

With continued reference to FIG. 1B, the first through hole 111F and the second through hole 111G may be filled with the core dielectric material 1120 at this stage. The core dielectric material layer 1120 may be a polymer layer (e.g., an Ajinomoto build-up film (ABF) or other suitable dielectric material(s)), and may be applied using a lamination technique or other suitable deposition process. However, any other suitable alternative material and method of formation may be used. In some embodiments, the core dielectric material layer 1120 includes a base material and fillers embedded in the base material. The details thereof will be described later in accompanying with FIG. 1F.

Referring to FIG. 1C with reference to FIG. 1B, the core dielectric material layer 1120 may be patterned through suitable removal process (e.g., laser drilling, etching, the like, a combination thereof, etc.) to form a core dielectric layer 1120 including a cavity 112G. The core layer 111 and the core dielectric layer 112 may be collectively viewed as a core structure 110. In some embodiments, the cavity 112G of the core dielectric layer 112 is located within the second through hole 111G of the core layer 111. For example, the second inner sidewall 111e of the core layer 111 defining the second through hole 111G remains covered by the core dielectric layer 112. The cavity 112G may be defined by an inner sidewall 112e of the core dielectric layer 112. The inner sidewall 112e may be substantially straight or may be slanted, depending on the process parameters and the applied removal techniques. For example, a maximum lateral dimension 112GL of the cavity 112G is in a range of about 100 μm to about 250 μm, or some other suitable value. It is appreciated that although a single cavity 112G is illustrated as an example, a plurality of cavities with the same size or different sizes is possible depending on process and product requirements.

Referring to FIG. 1D with reference to FIG. 1C, a through core via 113 may be formed to extend through the core dielectric layer 112. The through core via 113 may include one or more conductive material(s) such as copper, silver, gold, aluminum, titanium, alloy thereof, combinations thereof, etc. The through core via 113 laterally surrounded by the core dielectric layer 112 may provide a vertical and electrical connection between two opposing sides of the core structure 110. For example, the through core via 113 extends between the first surface 112a and the second surface 112b of the core dielectric layer 112. In some embodiments, the through core via 113 is a plated through hole (PTH). In some embodiments, the through core via 113 includes concave sidewalls which form a tapered or hourglass shape. For example, the through core via 113 includes a first portion 1131 and a second portion 1132 connected to the first portion 1131, where the first portion 1131 is tapered from the first surface 112a toward the second surface 112b, and the second portion 1132 is tapered from the second surface 112b toward the first surface 112a. The minimum lateral dimension 113M of the through core via 113 may be located at the interface of the first portion 1131 and the second portion 1132. The maximum lateral dimension 1131R of the first portion 1131 may be in a range of about 20 μm to about 100 μm, or some other suitable value. The maximum lateral dimension 1132R of the second portion 1132 may be similar to the maximum lateral dimension 1131R, within process variations.

In some embodiments, the first portion 1131 of the through core via 113 is formed by: removing a portion of the core dielectric layer 112 from the first surface 112a through suitable removal process (e.g., laser drilling, etching, the like, a combination thereof, etc.) to form a first opening (not individually labeled); forming one or more conductive material(s) in the first opening through plating or any suitable deposition process; optionally performing a planarization process to remove excess conductive material(s) from the first surface 112a. After forming the first portion 1131 of the through core via 113, the structure may be flipped over to form the second portion 1132 of the through core via 113 using the same (or similar) steps for forming the first portion 1131. It is appreciated that the cross-sectional profile of the through core via 113 illustrated herein is an example, and the cross-sectional profile of the through core via 113 may be a rectangular shape or other suitable shape, depending on process and product requirements. For example, the second portion 1132 is omitted, and the first portion 1131 extends between the first and second surfaces (112a and 112b) of the core dielectric layer 112.

With continued reference to FIG. 1D, a first conductive pattern 1211 may be formed on the first portion 1131 of the through core via 113 and may horizontally extend on the first surface 112a of the core dielectric layer 112. A second conductive pattern 1212 may be formed on the second portion 1132 of the through core via 113 and may horizontally extend on the second surface 112a of the core dielectric layer 112. The first conductive pattern 1211 and the second conductive pattern 1212 may each include conductive pads, conductive lines, or the like. For example, the first conductive pattern 1211 is formed by: forming a seed material layer on the first portion 1131 of the through core via 113 and the first surface 112a of the core dielectric layer 112; forming a patterned mask layer on the seed material layer, where the patterned mask layer has openings accessibly exposing the predetermined locations for forming the first conductive pattern 1211; plating one or more conductive material(s) on the seed material layer and within the openings of the patterned mask layer; removing the patterned mask layer; removing excess portions of the seed material layer on which no plated conductive material is formed. The second conductive pattern 1212 may be formed by the same/similar steps for forming the first conductive pattern 1211. However, any other suitable alternative material and method of formation may be used.

Referring to FIG. 1E with reference to FIG. 1D, a semiconductor device 130 may be disposed within the cavity 112G of the core structure 110. For example, after forming the through core via 113 and the first and second conductive patterns (1211 and 1212), the second conductive pattern 1212 is attached to a tape film 51. The tape film 51 may include suitable material to provide structural support for the subsequent processing. The semiconductor device 130 may be picked and placed on the tape film 51 and disposed within the cavity 112G of the core structure 110. In some embodiments, the semiconductor device 130 includes a first surface 130a, a second surface 130b opposite to the first surface 130a and attached to the tape film 51, and a sidewall 130c connected to the first surface 130 and the second surface 130b. The lateral dimension of the semiconductor device 130 may be less than the maximum lateral dimension 112GL (labeled in FIG. 1C) of the cavity 112G. For example, a gap G1 is formed between the sidewall 130c of the semiconductor device 130 and the inner sidewall 112e of the core dielectric layer 112, where the lateral distance of the gap G1 is non-zero.

In some embodiments, the semiconductor device 130 is a passive device including capacitors, inductors, resistors, combinations thereof, etc. For example, the semiconductor device 130 is a silicon capacitor which includes a semiconductor substrate (e.g., Si substrate) and one or more capacitor(s) formed in/on the semiconductor substrate. It is understood that other types of capacitors may be used. The semiconductor device 130 may be free of active devices. In some embodiments, the semiconductor device 130 includes active devices (e.g., transistors, diodes, etc.) and passive devices (e.g., capacitors, inductors, resistors, etc.). The semiconductor device 130 may be any suitable type of integrated circuit devices depending on product requirements. The semiconductor device 130 may include conductive connectors 132 distributed on the first surface 130a. In some embodiments, a thickness 130H of the semiconductor device 130 measured between the first surface 130a and the second surface 130b is in a range of about 150 μm to about 350 μm, or some other suitable value.

Referring to FIG. 1F with reference to FIG. 1E, a first dielectric layer 1221 may be formed on the tape film 51 to cover the core structure 110 and the semiconductor device 130. In some embodiments, the first conductive pattern 1211, the second conductive pattern 1212, and the semiconductor device 130 are covered by the first dielectric layer 1221. The first dielectric layer 1221 may fill the gap G1 surrounding the sidewall 130c of the semiconductor device 130. In other word, the first dielectric layer 1221 separates the semiconductor device 130 from the core dielectric layer 112 of the core structure 110. The core dielectric layer 112 may separate the core layer 111 from the first dielectric layer 1221. The first dielectric layer 1221 may be a polymer layer (e.g., an ABF or other suitable dielectric material(s)), and may be applied using a lamination technique or other suitable deposition process. However, any other suitable alternative material and method of formation may be used.

With continued reference to FIG. 1F, the first dielectric layer 1221 and the core dielectric layer 112 may be made of different materials. In some embodiments, the first dielectric layer 1221 includes a base material 1221M and fillers 1221F embedded in the base material 1221M. The core dielectric layer 112 may include a base material 112M and fillers 112F embedded in the base material 112M. The amount of the fillers 112F per unit volume of the core dielectric layer 112 may be less than the amount of the fillers 1221F per unit volume of the first dielectric layer 1221. As shown in the schematic and enlarged views, the first surface 1221a of the first dielectric layer 1221 may be rougher than the first surface 112a of the core dielectric layer 112. Since the core dielectric layer 112 has a less amount of the fillers 112F, the surface roughness of the core dielectric layer 112 is less than the surface roughness of the first dielectric layer 1221. The core dielectric layer 112 having less surface roughness may facilitate reducing the residues generated during the formation of the through core via 113. Since the first dielectric layer 1221 is formed on the tape film 51 and the second conductive pattern 1212 is attached to the tape film 51, the second surface 1221b of the first dielectric layer 1221 opposite to the first surface 1221a may be substantially leveled (or coplanar) with the lower surface 1212b of the second conductive pattern 1212 and the second surface 130b of the semiconductor device 130. The second surface 1221b of the first dielectric layer 1221 may be smoother than the first surface 1221a.

Referring to FIG. 1G with reference to FIG. 1F, a second dielectric layer 1222 may be formed on the first dielectric layer 1221 to cover the second conductive pattern 1212 and the semiconductor device 130. In some embodiments, after forming the first dielectric layer 1221 and before forming the second dielectric layer 1222, the tape film 51 may be removed through any suitable removal process to accessibly expose the second surface 1221b of the first dielectric layer 1221, the lower surface 1212b of the second conductive pattern 1212, and the second surface 130b of the semiconductor device 130. The second dielectric layer 1222 may then cover the second surface 1221b of the first dielectric layer 1221, the lower surface 1212b of the second conductive pattern 1212, and the second surface 130b of the semiconductor device 130. The second dielectric layer 1222 may be a polymer layer (e.g., an ABF or other suitable dielectric material(s)), and may be applied using a lamination technique or other suitable deposition process. However, any other suitable alternative material and method of formation may be used. The second dielectric layer 1222 and the first dielectric layer 1221 may be made of different materials such that a visible interface F1 is formed therebetween. In alternative embodiments, the second dielectric layer 1222 and the first dielectric layer 1221 are of the same/similar material(s).

Referring to FIG. 1H with reference to FIG. 1G, a third conductive pattern 1213 may be formed in and on the first dielectric layer 1221 to be in physical and electrical contact with the first conductive pattern 1211 and the conductive connectors 132 of the semiconductor device 130. A fourth conductive pattern 1214 may be formed in and on the second dielectric layer 1222 to be in physical and electrical contact with the second conductive pattern 1212. The third conductive pattern 1213 and the fourth conductive pattern 1214 may each include conductive pads, conductive vias, conductive lines, etc. For example, the conductive vias 1213V of the third conductive pattern 1213 penetrate through the first dielectric layer 1221 to land on the first conductive pattern 1211 and the conductive connectors 132. The conductive vias 1214V of the fourth conductive pattern 1214 may penetrate through the second dielectric layer 1222 to land on the second conductive pattern 1212.

With continued reference to FIG. 1H, the conductive via 1213V of the third conductive pattern 1213 and the through core via 113 are disposed in a stacked and vertically aligned manner. In some embodiments, the conductive via 1214V of the fourth conductive pattern 1214 and the through core via 113 are disposed in a stacked and vertically aligned manner. In alternative embodiments, the conductive vias(s) (1213V and/or 1214V) and the through core via 113 are arranged in a laterally staggered manner. In some embodiments, the respective conductive vias 1213V and the respective conductive vias 1214V are tapered in opposing directions. For example, the respective conductive vias 1213V is tapered from the first surface 1221a toward the second surface 1221b. The respective conductive vias 1214V may be tapered in a direction from the second surface 1221b toward the first surface 1221a.

The third conductive pattern 1213 may be formed by: removing portions of the first dielectric layer 1221 through suitable removal process (e.g., laser drilling, etching, the like, a combination thereof, etc.) to form via openings accessibly exposing at least a portion of the first conductive pattern 1211 and at least a portion of the conductive connectors 132; forming one or more conductive materials (e.g., copper, silver, gold, aluminum, titanium, alloy thereof, etc.) in the via openings and on the first surface 1221a of the first dielectric layer 1221; patterning the conductive materials to form the third conductive pattern 1213. The fourth conductive pattern 1214 may be formed by using the similar steps for forming the third conductive pattern 1213. However, any other suitable alternative material and method of formation may be used.

With continued reference to FIG. 1H, a third dielectric layer 1223 may be formed on the first surface 1221a of the first dielectric layer 1221 to cover the third conductive pattern 1213. A fourth dielectric layer 1224 may be formed on the second dielectric layer 1222 to cover the fourth conductive pattern 1214. The third dielectric layer 1223 and/or the fourth dielectric layer 1224 may be a polymer layer (e.g., an ABF or other suitable dielectric material(s)), and may be applied using a lamination technique or other suitable deposition process. However, any other suitable alternative material and method of formation may be used. In some embodiments, the third dielectric layer 1223 and the underlying first dielectric layer 1221 are made of different materials, and a visible interface F2 is formed therebetween. In alternative embodiments, the third dielectric layer 1223 and the first dielectric layer 1221 are of the same/similar material(s). In some embodiments, the fourth dielectric layer 1224 and the second dielectric layer 1222 are made of different materials, and a visible interface F3 is formed therebetween. In alternative embodiments, the fourth dielectric layer 1224 and the second dielectric layer 1222 are of the same/similar material(s).

With continued reference to FIG. 1H, a fifth conductive pattern 1215 may be formed in and on the third dielectric layer 1223 to be in physical and electrical contact with the third conductive pattern 1213. A sixth conductive pattern 1216 may be formed in and on the fourth dielectric layer 1224 to be in physical and electrical contact with the fourth conductive pattern 1214. The fifth conductive pattern 1215 and the sixth conductive pattern 1216 may each include conductive pads, conductive vias, conductive lines, etc. The fifth conductive pattern 1215 may be similar to the third conductive pattern 1213, the sixth conductive pattern 1216 may be similar to the fourth conductive pattern 1214, and thus the details thereof are not repeated herein for the sake of brevity.

In some embodiments, the conductive vias 1215V of the fifth conductive pattern 1215 and the conductive vias 1216V of the sixth conductive pattern 1216 are tapered in opposing directions. In some embodiments, the conductive vias 1215V of the fifth conductive pattern 1215 and the conductive vias 1213V of the third conductive pattern 1213 are disposed in a stacked and vertically aligned manner. In alternative embodiments, the conductive vias 1215V and the conductive vias 1213V are arranged in a laterally staggered manner. In some embodiments, the conductive vias 1216V of the sixth conductive pattern 1216 and the conductive vias 1214V of the fourth conductive pattern 1214 are disposed in a stacked and vertically aligned manner. In alternative embodiments, the conductive vias 1216V and the conductive vias 1214V are arranged in a laterally staggered manner.

With continued reference to FIG. 1H, the third conductive pattern 1213 and the first dielectric layer 1221 may be collectively viewed as a first build-up layer BU1, the fourth conductive pattern 1214 and the second dielectric layer 1222 may be collectively viewed as a second build-up layer BU2, the fifth conductive pattern 1215 and the third dielectric layer 1223 may be collectively viewed as a third build-up layer BU3, and the sixth conductive pattern 1216 and the fourth dielectric layer 1224 may be collectively viewed as a fourth build-up layer BU4. The first, second, third, and fourth build-up layers (BU1, BU2, BU3, and BU4) may be collectively viewed as a build-up structure 120. The first and third build-up layers (BU1 and BU3) are located at the first side 110a of the core structure 110, and the second and fourth build-up layers (BU2 and BU4) are located at the second side 110b of the core structure 110. It is appreciated that four build-up layers illustrated herein as an example, and less than four or more than four build-up layers are possible, depending on circuit and product requirements.

Still referring to FIG. 1H, the semiconductor device 130 may be electrically coupled to the second side 110b of the core structure 110 through the through core via 113 and the first and/or third build-up layer(s) (BU1 and/or BU3) located at the first side 110a of the core structure 110. In alternative embodiments, the semiconductor device 130 includes additional conductive connectors (not shown) distributed on the second surface 130b, and the second build-up layer BU2 located at the second side 110b of the core structure 110 may be in direct and electrical contact with the additional conductive connectors of the semiconductor device 130.

Referring to FIG. 1I with reference to FIG. 1H, a first resist layer 141 may be formed on the third dielectric layer 1223, where the first resist layer 141 includes openings exposing at least a portion of the fifth conductive pattern 1215. A plurality of first conductive terminals 151 may be formed on the fifth conductive pattern 1215 and within the openings of the first resist layer 141. A second resist layer 142 may be formed on the fourth dielectric layer 1224, where the second resist layer 142 includes openings exposing at least a portion of the sixth conductive pattern 1216. A plurality of second conductive terminals 152 may be formed on the sixth conductive pattern 1216 and within the openings of the second resist layer 142. The first resist layer 141 and/or the second resist layer 142 may be a protective layer that covers portions of the underlying structure to protect it from damage. The first resist layer 141 and/or the second resist layer 142 may be formed of a polymer layer. For example, the first resist layer 141 and the second resist layer 142 are solder resist layers, when the first conductive terminals 151 and the second conductive terminals 152 are solder balls or solder bumps. Alternatively, the first resist layer 141 and/or the second resist layer 142 may be made of photoresist. The first conductive terminals 151 and/or the second conductive terminals 152 may include metal pillars, controlled collapse chip connection (C4) bumps, micro-bumps, electroless nickel-electroless palladium-immersion gold (ENEPIG) formed bumps, ball grid array (BGA) bumps, or the like.

The structure shown in FIG. 1I may be viewed as a substrate structure 10. In some embodiments, an outer sidewall 10W of the substrate structure 10 includes outer sidewalls (141W and 142W) of the first and second resist layers (141 and 142), outer sidewalls (1221W, 1222W, 1223W, and 1224W) of the first, second, third, and fourth dielectric layers (1221, 1222, 1223, and 1224), and an outer sidewall 112W of the core dielectric layer 112 of the core structure 110, where these outer sidewalls may be substantially aligned (or coplanar) with one another, within process variations. The core structure 110 of the substrate structure 10 includes the core layer 111 and the core dielectric layer 112, where the core layer 111 may be a non-organic core and the core dielectric layer 112 wraps around the core layer 111. In this manner, the core structure 110 may have stronger strength, improved hardness, and lower dielectric loss, as compared to the organic core without wrapped around by the suitable dielectric layer. The semiconductor device 130 may be disposed in the cavity 112G of the core structure 110 and laterally surrounded by the first dielectric layer 1211. In this manner, the arrangement of the semiconductor device 130 is more flexible. Since the core dielectric layer 112 is made of a material which has less amount of filler (as compared to the dielectric layers in the build-up layers), the core structure 110 having the cavity 112G for accommodating the semiconductor device 130 is easier to fabricated. By embedding the semiconductor device 130 in the core structure 110, the functionality of the substrate structure 10 may be improved, and the design of the substrate structure 10 becomes more flexible.

Still referring to FIG. 1I, the substrate structure 10 may be coupled to one or more package component (not shown). For example, a package component (not shown) is coupled to the first conductive terminals 151 and another package component (not shown) is coupled to the second conductive terminals 152. The package component(s) may be or include a printed circuit board (PCB), a printed wiring board, an interposer, a packaged chip/die, and/or other carrier that is capable of carrying integrated circuits. The substrate structure 10 may be a part of a Chip-On-Wafer-On-Substrate (CoWoS) package or other type of a semiconductor package. The substrate structure 10 may be part of an electronic system for such as computers (e.g., high-performance computer), computational devices used in conjunction with an artificial intelligence system, wireless communication devices, computer-related peripherals, entertainment devices, etc. It should be noted that other electronic applications are also possible.

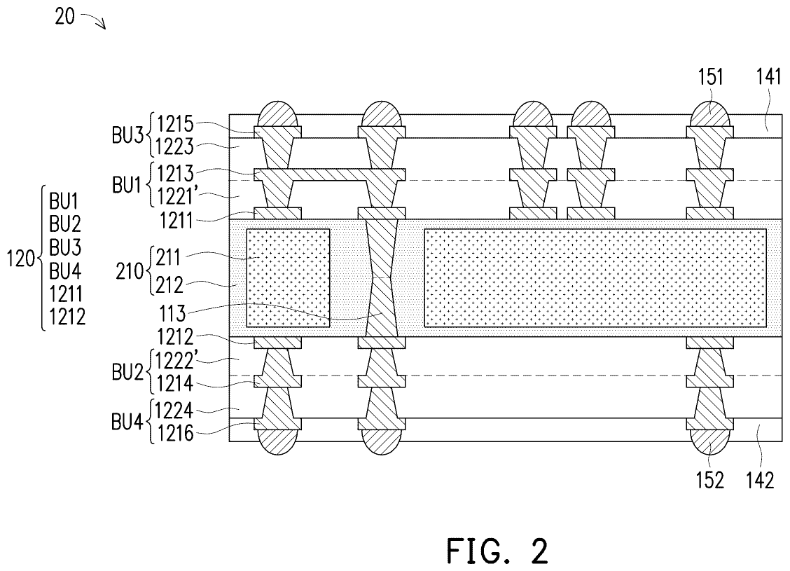

FIGS. 2-6 are schematic cross-sectional views of various variations of a substrate structure, in accordance with some embodiments. The substrate structures shown in FIGS. 2-6 may be similar to the substrate structure 10 shown in FIG. 1I, where like reference numerals indicate like elements.

Referring to FIG. 2 and with reference to FIG. 1I, the substrate structure 20 is similar to the substrate structure 10 shown in FIG. 1I, and thus the details thereof are not repeated for the sake of brevity. The difference between the substrate structures (20 and 10) includes that the substrate structure 20 is free of semiconductor device 130. For example, the core structure 210 of the substrate structure 20 includes a core layer 211 and a core dielectric layer 212 wrapping around the core layer 211. The materials and the forming methods of the core layer 211 and the core dielectric layer 212 may be similar to those of the core layer 111 and the core dielectric layer 112, and thus the details thereof are not repeated herein. The core structure 210 may be free of cavity and no semiconductor device is embedded in the core structure 210. Since there is no cavity formed in the core structure 210, the first dielectric layer 1221′ may be only formed at the first side 110a of the core structure 110 without extending to the second side 110b of the core structure 110. The second dielectric layer 1222′ may cover the second conductive pattern 1212.

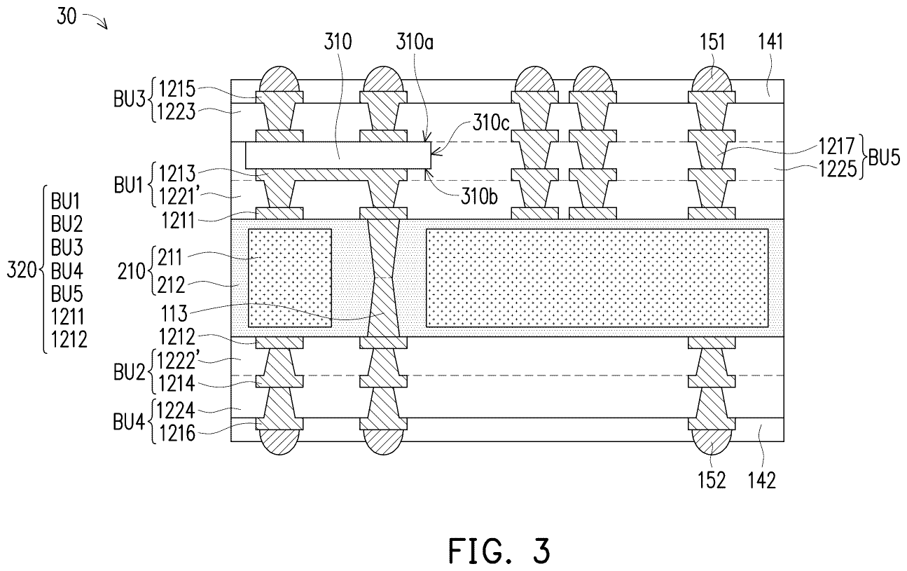

Referring to FIG. 3 and with reference to FIG. 1I and FIG. 2, the substrate structure 30 is similar to the substrate structure 10 shown in FIG. 1I, and thus the details thereof are not repeated for the sake of brevity. The difference between the substrate structures (30 and 10) includes that the core structure 210 of the substrate structure 30 is free of cavity, no semiconductor device is embedded in the core structure 210, and one or more electronic component(s) 310 may be embedded in the build-up structure 320 of the substrate structure 30. The core structure 210 of the substrate structure 30 is similar to the core structure 210 of the substrate structure 20 described in FIG. 2, so that the details of the core structure 210 are not repeated herein. Since there is no cavity formed in the core structure 210, the first dielectric layer 1221′ may be only formed at the first side 110a of the core structure 110 without extending to the second side 110b of the core structure 110. The second dielectric layer 1222′ may cover the second conductive pattern 1212.

It is appreciated that although a single electronic component 310 is illustrated herein, the number of the electronic components 310 may depend on circuit and product requirements and construes no limitation in the disclosure. The electronic component 310 may be or include a passive device such as a multilayer ceramic capacitor (MLCC), an integrated passive device (IPD), an integrated voltage regulator (IVR), or the like. When the electronic component 310 is a MLCC, it may be a fixed capacitor with a ceramic material acting as the dielectric. It may be constructed of two or more alternating layers of ceramic with metal layers acting as the electrodes.

With continued reference to FIG. 3 and FIG. 1I, as compared to the build-up structure 120, the build-up structure 320 may further include a fifth build-up layer BU5 interposed between the first build-up layer BU1 and the third build-up layer BU3. The fifth build-up layer BU5 may include a fifth dielectric layer 1225 interposed between the first dielectric layer 1221 and the third dielectric layer 1223, and a seventh conductive pattern 1217 embedded in the fifth dielectric layer 1225 and connecting the fifth conductive pattern 1215 to the third conductive pattern 1213. In some embodiments, the electronic component 310 is covered by the fifth dielectric layer 1225 of the fifth build-up layer BU5. The electronic component 310 may include a first side 310a facing the build-up layer BU3, a second side 310b opposite to the first side 310a and covered by the fifth dielectric layer 1225, and a sidewall 310c connected to the first side 310a and the second side 310b and covered by the fifth dielectric layer 1225. The electronic component 310 may include conductive connectors 312 distributed at the first side 310a. In some embodiments, the conductive connectors 312 are covered by the third dielectric layer 1223, and the conductive vias 1215V of the fifth conductive pattern 1215 may be in physical and electrical contact with the conductive connectors 312.

It is appreciated that the electronic component 310 may have a different configuration than shown. For example, the electronic component 310 includes additional conductive connectors (not individually labeled) distributed at the second side 310b and connected to the third conductive pattern 1213 of the first build-up layer BU1. In alternative embodiments, the electronic component 310 is embedded in the first dielectric layer 1221 of the first build-up layer BU1. In some other embodiments, a plurality of electronic components 310 is embedded in the build-up structure 320 and may be disposed at the same level (or disposed at different levels). The substrate structure 30 including the electronic component 310 embedded in the build-up structure 320 may improve the functionality and signal processing of the substrate structure 30. The flexibility of the design of the substrate structure 30 may be increased.

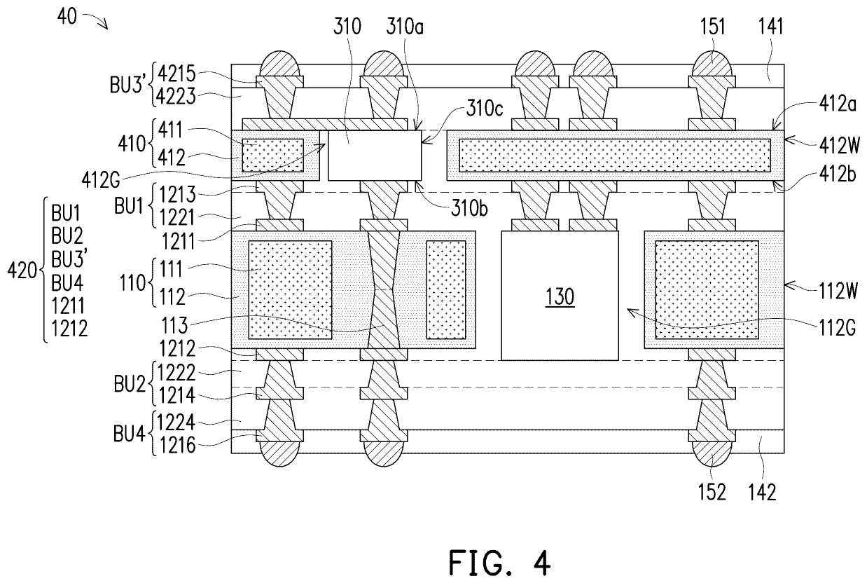

Referring to FIG. 4 and with reference to FIG. 1I and FIG. 3, the substrate structure 40 is similar to the substrate structure 10 shown in FIG. 1I, and thus the details thereof are not repeated for the sake of brevity. The difference between the substrate structures (40 and 10) includes that additional core structure 410 is interposed in the build-up structure 420 and one or more electronic component(s) 310 may be embedded in the core structure 410. For example, the core structure 410 is disposed on the first build-up layer BU1, covered by the third dielectric layer 4223 of the third build-up layer BU3′, and electrically connected to the third and fifth conductive patterns (1213 and 4215). In some embodiments, the fifth conductive pattern 4215 includes additional conductive traces directly overlying the core structure 410. The core structure 410 may be similar to the core structure 110. For example, the core structure 410 includes a core layer 411 and a core dielectric layer 412 wrapping around the core layer 411. The materials and the forming methods of the core layer 411 and the core dielectric layer 412 may be similar to those of the core layer 111 and the core dielectric layer 112, and thus the details thereof are not repeated herein. The core structure 410 may or may not include through core via, depending on circuit and product requirements.

With continued reference to FIG. 4 and FIGS. 1I and 3, the core dielectric layer 412 of the core structure 410 may include the first surface 412a on which the fifth conductive pattern 4215 is disposed, the second surface 412b opposite to the first surface 412a and connected to the third conductive pattern 1213, and the outer sidewall 412W substantially aligned (or coplanar) with the outer sidewall 112W of the core dielectric layer 112. The outer sidewalls (412W and 112W) may be accessibly exposed by the build-up structure 420 and may be substantially aligned (or coplanar) with the outer sidewalls of the dielectric layers (e.g., 4223, 1221, 1222, and 1224) of the build-up structure 420. The core dielectric layer 412 of the core structure 410 may include one or more cavity 412G which is similar to the cavity 112G of the core structure 110. The electronic component 310 may be disposed in the cavity 412G, and the cavity 412G may be filled with the third dielectric layer 4223 to bury the electronic component 310 therein. The electronic component 310 may be similar to the electronic component 310 described in FIG. 3. In some embodiments, the first side 310a, the second side 310b, and the sidewall 310c of the electronic component 310 are covered by the third dielectric layer 4223. The substrate structure 40 including multiple core structures (e.g., 110 and 410) may enhance the strength and hardness, and may achieve lower dielectric loss (as compared to the application of the organic core). The substrate structure 40 including the electronic component 310 embedded in the core structure 410 may improve the functionality and signal processing. The flexibility of the design of the substrate structure 40 may be increased.

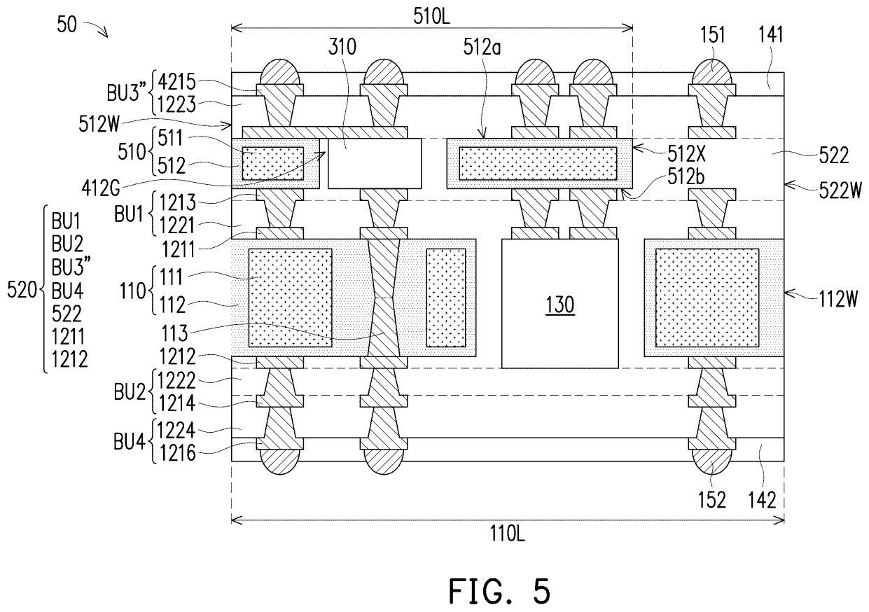

Referring to FIG. 5 and with reference to FIG. 4, the substrate structure 50 is similar to the substrate structure 40 shown in FIG. 4, and thus the details thereof are not repeated for the sake of brevity. The difference between the substrate structures (50 and 40) includes that the core structure 510 embedded in the build-up structure 520 has a maximum lateral dimension 510L less than a maximum lateral dimension 110L of the core structure 110. The maximum lateral dimension of the build-up structure 520 may be substantially equal to the maximum lateral dimension 110L of the core structure 110, within process variations. For example, the core structure 510 includes a core layer 511 and a core dielectric layer 512 wrapping around the core layer 511. The materials and the forming methods of the core layer 511 and the core dielectric layer 512 may be similar to those of the core layer 111 and the core dielectric layer 112, and thus the details thereof are not repeated herein. The core structure 510 may or may not include through core via, depending on circuit and product requirements.

In some embodiments, the build-up structure 520 includes additional dielectric layer 522 interposed between the first dielectric layer 1221 and the third dielectric layer 1223. The dielectric layer 522 may fill the cavity 412G of the core structure 510 and laterally surround the electronic component 310. The dielectric layer 522 may laterally cover at least one side of the core structure 510. For example, a first outer sidewall 512X and the second surface 512b of the core dielectric layer 512 are covered by the dielectric layer 522. For example, the outer sidewall 522W of the dielectric layer 522 may be substantially leveled (or coplanar) with the outer sidewall 112W of the core substrate 110. The first surface 512a of the core dielectric layer 512 may be covered by the third dielectric layer 1223. The core substrate 510 may include a second outer sidewall 512W opposite to the first outer sidewall 512X and accessibly exposed by the dielectric layer 522. In alternative embodiments, both of the first and second outer sidewalls (512X and 512W) are covered by the dielectric layer 522. In some embodiments, the dielectric layer 522 is free of conductive vias formed therein. Alternatively, one or more conductive via(s) may penetrate through the dielectric layer 522 to connect the fifth conductive pattern 4215 to the third conductive pattern 1213. The core structure 510 of the substrate structure 50 may be provided as a local core which is stacked over the core structure 110 and embedded in the build-up structure 520. In this arrangement, the flexibility of the design of the substrate structure 50 may be increased.

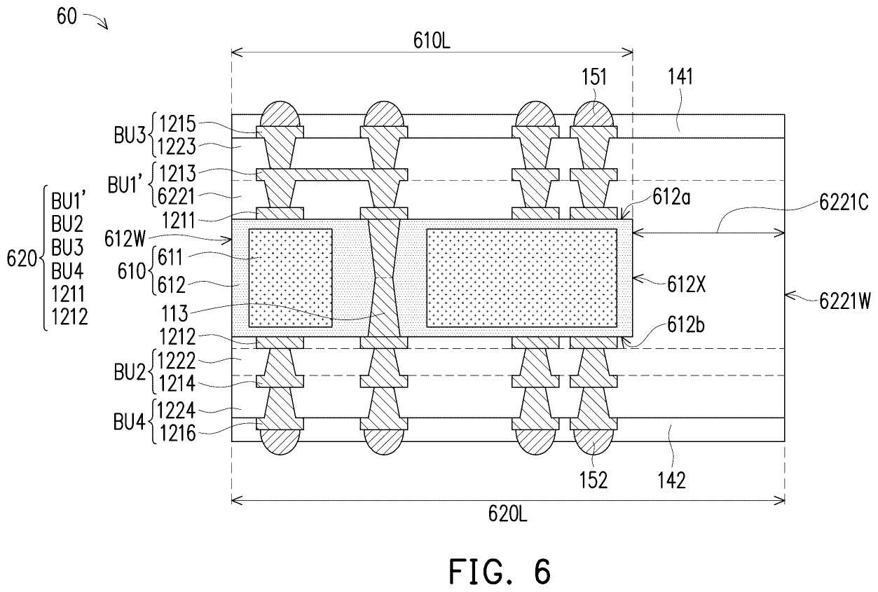

Referring to FIG. 6 and with reference to FIG. 2, the substrate structure 60 is similar to the substrate structure 20 shown in FIG. 2, and thus the details thereof are not repeated for the sake of brevity. The difference between the substrate structures (60 and 20) includes that the core structure 610 of the substrate structure 60 has a maximum lateral dimension 610L less than a maximum lateral dimension 620 of the build-up structure 620. For example, the core structure 610 includes a core layer 611 and a core dielectric layer 612 wrapping around the core layer 611. The materials and the forming methods of the core layer 611 and the core dielectric layer 612 may be similar to those of the core layer 111 and the core dielectric layer 112, and thus the details thereof are not repeated herein.

In some embodiments, the first surface 612a, the second surface 612b, and the first outer sidewall 612X connected to the first and second surfaces (612a and 612b) of the core dielectric layer 612 are covered by the first dielectric layer 6221 of the first build-up layer BU1′. The thickness 6221C of the first dielectric layer 6221 on the first outer sidewall 612X of the core structure 610 may be at least (or greater than) about 1 μm, where the thickness 6221C may be measured between the first outer sidewall 612X of the core dielectric layer 612 and the outer sidewall 6221W of the first dielectric layer 6221 facing the first outer sidewall 612X. The core substrate 610 may include the second outer sidewall 612W opposite to the first outer sidewall 612X and exposed by the first dielectric layer 6221. In alternative embodiments, both of the first and second outer sidewalls (612X and 612W) are covered by the first dielectric layer 6221. The substrate structure 60 includes the core structure 610 provided as a local core and embedded in the build-up structure 620. In this arrangement, the flexibility of the design of the substrate structure 60 may be increased. Many variations of the above examples described in FIGS. 2-6 are contemplated by the disclosure.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

In accordance with some embodiments, a device includes a substrate structure including a first core structure and a build-up structure. The first core structure includes a first side, a second side opposite to each other, a first core layer, and a first core dielectric layer wrapping around the first core layer, where the first core layer is non-organic. The build-up structure is disposed on the first and second sides of the first core structure, the build-up layer includes a first dielectric layer at least covering the first side of the first core structure, and materials of the first dielectric layer and the first core dielectric layer are different.

In accordance with some embodiments, a device includes a substrate structure including a first build-up layer, a second build-up layer electrically coupled to the first build-up layer, and a first core structure sandwiched between the first build-up layer and the second build-up layer. The first build-up layer includes a first dielectric layer and a first conductive pattern in the first dielectric layer. The first core structure includes a non-organic core and a core dielectric layer wrapping around the non-organic core, where a surface roughness of the core dielectric layer is less than that of the first dielectric layer.

In accordance with some embodiments, a method includes: wrapping around an non-organic core with a core dielectric layer, wherein the core dielectric layer comprises a first side, a second side opposite to the first side, and a cavity passing through the first side and the second side; forming a first conductive pattern and a second conductive pattern on the first side and the second side of the core dielectric layer, respectively; placing a semiconductor device in the cavity; forming a first dielectric layer to cover the core dielectric layer, the first conductive pattern, the second conductive pattern, and the semiconductor device; and forming additional build-up layers in the first dielectric layer and on the first conductive pattern and the second conductive pattern, wherein the additional build-up layers are electrically coupled to the semiconductor device.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device, comprising:
a substrate structure comprising:
a first core structure comprising a first side and a second side opposite to each other, the first core structure further comprising:
a first core layer, wherein the first core layer is non-organic; and
a first core dielectric layer wrapping around the first core layer; and
a build-up structure disposed on the first side and the second side of the first core structure, the build-up layer comprising a first dielectric layer at least covering the first side of the first core structure, wherein materials of the first dielectric layer and the first core dielectric layer are different.

2. The device of claim 1, wherein the first core dielectric layer comprises first fillers, the first dielectric layer comprises second fillers, and an amount of the first fillers per unit volume of the first core dielectric layer is less than that of the second fillers per unit volume of the first dielectric layer.

3. The device of claim 1, wherein a surface roughness of the first core dielectric layer is less than that of the first dielectric layer.

4. The device of claim 1, wherein the substrate structure further comprises:
a through core via penetrating through the first side and the second side of the first core structure and electrically coupled to the build-up structure, the through core via comprising a first portion and a second portion connected to the first portion, wherein the first portion and the second portion are tapered in opposing directions.

5. The device of claim 1, wherein the substrate structure further comprises:
a semiconductor device disposed in a cavity of the first core structure and electrically coupled to the build-up structure, wherein the cavity passes through the first side and the second side of the first core structure, and a portion of the first dielectric layer extends into the cavity to surround the semiconductor device.

6. The device of claim 5, wherein the build-up structure further comprises:
a first conductive pattern disposed on the first side of the first core structure, electrically coupled to the semiconductor device, and embedded in the first dielectric layer; and
a second conductive pattern disposed on the second side of the first core structure, electrically coupled to the first conductive pattern, and laterally covered by the first dielectric layer.

7. The device of claim 1, wherein outer sidewalls of the first core dielectric layer and the first dielectric layer are substantially coplanar.

8. The device of claim 1, wherein the substrate structure further comprises:
a passive device embedded in the build-up structure.

9. The device of claim 1, wherein the substrate structure further comprises:
a second core structure interposed in the build-up structure, the second core structure comprising a first side, a second side opposite to the first side and facing the first core structure, and a cavity passing through the first and second sides of the second core structure; and
a passive device disposed in the cavity of the second core structure and wrapped around by a second dielectric layer of the build-up structure.

10. The device of claim 9, wherein the second core structure further comprises a second core layer and a second core dielectric layer wrapping around the second core layer, the second core layer is non-organic, and materials of the second core dielectric layer and the second dielectric layer are different.

11. The device of claim 9, wherein a maximum lateral dimension of the second core structure is less than that of the first core structure.

12. The device of claim 1, wherein a maximum lateral dimension of the first core structure is less than that of the build-up structure.

13. A device, comprising:
a substrate structure comprising:
a first build-up layer comprising a first dielectric layer and a first conductive pattern in the first dielectric layer;
a second build-up layer electrically coupled to the first build-up layer; and
a first core structure sandwiched between the first build-up layer and the second build-up layer, the first core structure comprising:
a non-organic core; and
a core dielectric layer wrapping around the non-organic core, wherein a surface roughness of the core dielectric layer is less than that of the first dielectric layer.

14. The device of claim 13, wherein the substrate structure further comprises:
a semiconductor device disposed in a cavity of the first core structure and electrically coupled to the first conductive pattern, wherein a portion of the first dielectric layer extends into the cavity to surround the semiconductor device.

15. The device of claim 14, wherein the substrate structure further comprises:
additional conductive pattern on a side of the first core structure opposite to the first build-up layer, the additional conductive pattern being between the first core structure and the second build-up layer and laterally covered by the first dielectric layer.

16. The device of claim 13, wherein the substrate structure further comprises:
a second core structure stacked over the first build-up layer, the second core structure comprising another non-organic core and another core dielectric layer wrapping around the another non-organic core; and
a passive device disposed in a cavity of the second core structure.

17. The device of claim 13, wherein the core structure comprises a first outer sidewall and a second outer sidewall opposite to the first outer sidewall, the first outer sidewall is substantially aligned with the first dielectric layer and the second dielectric layer, and the second outer sidewall is covered by the first dielectric layer.

18. A method, comprising:
wrapping around a non-organic core with a core dielectric layer, wherein the core dielectric layer comprises a first side, a second side opposite to the first side, and a cavity passing through the first side and the second side;
forming a first conductive pattern and a second conductive pattern on the first side and the second side of the core dielectric layer, respectively;
placing a semiconductor device in the cavity;
forming a first dielectric layer to cover the core dielectric layer, the first conductive pattern, the second conductive pattern, and the semiconductor device; and
forming additional build-up layers in the first dielectric layer and on the first conductive pattern and the second conductive pattern, wherein the additional build-up layers are electrically coupled to the semiconductor device.

19. The method of claim 18, further comprising:
attaching the second conductive pattern to a tape film before placing the semiconductor device in the cavity;
attaching the semiconductor device to the tape film when placing the semiconductor device in the cavity;
forming the first dielectric layer on the tape film to cover the core dielectric layer, the first conductive pattern, the second conductive pattern, and the semiconductor device; and
releasing the tape film before forming the additional build-up layers.

20. The method of claim 18, wherein before forming the first conductive pattern and the second conductive pattern, the method further comprises:
forming a through core via in the core dielectric layer, wherein the through core via comprises a first portion and a second portion connected to the first portion, wherein the first portion and the second portion are tapered in opposing directions.
